(19) United States
(12) Patent Application Publication
(10) Pub. No.: US 2026/0020347 A1
(43) Pub. Date: Jan. 15, 2026

(54) DISPLAY SUBSTRATE AND DISPLAY APPARATUS

(71) Applicants: BEIJING BOE DISPLAY TECHNOLOGY CO., LTD., BEIJING (CN); BOE TECHNOLOGY GROUP CO., LTD., BEIJING (CN)

(72) Inventors: YINGMENG MIAO, BEIJING (CN); YANPING LIAO, BEIJING (CN); DONGCHUAN CHEN, BEIJING (CN); TAO YANG, BEIJING (CN); WEI QIN, BEIJING (CN); JIANTAO LIU, BEIJING (CN); YUE YANG, BEIJING (CN)

(73) Assignees: BEIJING BOE DISPLAY TECHNOLOGY CO., LTD., BEIJING (CN); BOE TECHNOLOGY GROUP CO., LTD., BEIJING (CN)

(21) Appl. No.: 18/995,684

(22) PCT Filed: Apr. 29, 2024
(86) PCT No.: PCT/CN2024/090545

§ 371 Date: Jan. 16, 2025

(30) Foreign Application Priority Data
May 24, 2023 (CN) 202310594994.3

(51) Int. Cl. H10D 86/40; G02F 1/1362; G02F 1/1368; H10D 86/60

(52) U.S. Cl. CPC H10D 86/441; G02F 1/136286; G02F 1/1368; H10D 86/60

(57) ABSTRACT

A display substrate and a display apparatus are provided. The display substrate includes a base substrate and data lines, gate lines, a first electrode layer, and transistors. The first electrode layer is on a side of the data lines away from the base substrate; each transistor includes a gate electrode, a first electrode and a second electrode, second electrodes of the transistors are electrically connected to the first electrode layer. The gate lines are located on a side of the data lines away from the base substrate, the gate electrodes of the transistors are arranged on the same layer as the data lines, and an orthographic projection of the gate electrode of at least one transistor on the base substrate is spaced apart from an orthographic projection of the gate line.

The present application claims the priority of the Chinese patent application No. 202310594994.3 filed on May 24, 2023, the disclosure content of which is incorporated herein by reference in its entirety and constitutes a part of the present application.

### TECHNICAL FIELD

The embodiments of the present disclosure relate to a display substrate and a display apparatus.

### BACKGROUND

A liquid crystal display (LCD) panel has an advanced super dimension switching (ADS) display mode, where the ADS horizontal electric field liquid crystal mode and other technologies improve the transmittance of the liquid crystal display panel by improving the electrodes or partially adjusting the backlight brightness, and improve the contrast and brightness of the liquid crystal display panel.

The LCD panels that use high advanced-super dimensional switching (HADS) display mode with a high aperture ratio has the characteristics of high aperture ratio, high resolution, high transmittance, and wide viewing angle.

### SUMMARY

The embodiments of the present disclosure provide a display substrate and a display apparatus.

The present disclosure provides a display substrate, which includes a base substrate and a plurality of data lines, a plurality of gate lines, a first electrode layer, and a plurality of transistors located on the base substrate. The plurality of data lines are arranged in a first direction; the plurality of gate lines are arranged in a second direction, and the second direction intersects with the first direction; the first electrode layer is located on a side of a film layer where the plurality of data lines are located away from the base substrate; each of the plurality of transistors includes a gate electrode, a first electrode and a second electrode, gate electrodes of the plurality of transistors are electrically connected to the plurality of gate lines, first electrodes of the plurality of transistors are electrically connected to the plurality of data lines, and second electrodes of the plurality of transistors are electrically connected to the first electrode layer. The plurality of gate lines are located on a side of the plurality of data lines away from the base substrate, the gate electrodes of the plurality of transistors are arranged on the same layer as the plurality of data lines, and an orthographic projection of the gate electrode of at least one transistor on the base substrate is spaced apart from an orthographic projection of a gate line electrically connected to the gate electrode of the at least one transistor on the base substrate.

For example, according to an embodiment of the present disclosure, the display substrate further includes: a plurality of sub-pixels, the first electrode layer including a plurality of first electrodes arranged at intervals, and each sub-pixel including one of the plurality of first electrodes; a plurality of first connecting portions, located on a side of the plurality of gate lines away from the base substrate, and configured to connect the gate electrodes of the plurality of transistors to the plurality of gate lines. At least one gate line includes a plurality of protruding structures, each protruding structure is configured to be electrically connected to the gate electrode of a corresponding transistor through at least one of the plurality of first connecting portions, and the plurality of protruding structures include at least a first protruding structure and a second protruding structure; the plurality of sub-pixels include at least a first sub-pixel and a second sub-pixel, a transistor electrically connected to the first electrode of the first sub-pixel is a first transistor, a transistor electrically connected to the first electrode of the second sub-pixel is a second transistor, the gate electrode of the first transistor is electrically connected to the first protruding structure, the gate electrode of the second transistor is electrically connected to the second protruding structure, and a shape of the first protruding structure is different from that of the second protruding structure.

For example, according to an embodiment of the present disclosure, an area of the first protruding structure is larger than that of the second protruding structure.

For example, according to an embodiment of the present disclosure, the first protruding structure includes a first sub-protruding structure and a second sub-protruding structure, and the first sub-protruding structure and the second protruding structure are of substantially a same shape and are substantially equal in size.

For example, according to an embodiment of the present disclosure, the second sub-protruding structure is located on a side of the first sub-protruding structure away from the gate electrode electrically connected to the first sub-protruding structure.

For example, according to an embodiment of the present disclosure, in the second direction, a size of the second sub-protruding structure is larger than a size of the first sub-protruding structure.

For example, according to an embodiment of the present disclosure, in the first direction, a ratio of a distance between the first protruding structure and a data line closest to the first protruding structure to a distance between the second protruding structure and a data line closest to the second protruding structure is in a range from 0.8 to 1.2.

For example, according to an embodiment of the present disclosure, the data line closest to the first protruding structure has a different shape from the data line closest to the second protruding structure.

For example, according to an embodiment of the present disclosure, two data lines located on both sides of the first protruding structure include a first data line and a second data line, two data lines located on both sides of the second protruding structure include the second data line and a third data line or the first data line and a third data line, and the second data line or the first data line is located between the first protruding structure and the second protruding structure, and the first data line, the second data line, and the third data line have different shapes.

For example, according to an embodiment of the present disclosure, the first data line and the second data line, at positions corresponding to the first protruding structure, bent to two sides away from the first protruding structure.

For example, according to an embodiment of the present disclosure, a distance between the first data line and a gate electrode closest to the first data line is a first distance, a distance between the second data line and a gate electrode closest to the second data line is a second distance, a distance between the third data line and a gate electrode closest to the third data line is a third distance, and a ratio of the first distance, the second distance, and the third distance is (0.8˜1.2):(0.8˜1.2):(0.8˜1.2).

For example, according to an embodiment of the present disclosure, a shape of the gate electrode of the first transistor is approximately the same as that of the gate electrode of the second transistor, a shape of the first electrode of the first transistor is approximately the same as that of the first electrode of the second transistor, and a shape of the second electrode of the first transistor is approximately the same as that of the second electrode of the second transistor; and a ratio of a distance between the gate electrode of the first transistor and a data line electrically connected to the first transistor to a distance between the gate electrode of the second transistor and a data line electrically connected to the second transistor is in a range from 0.8 to 1.2.

For example, according to an embodiment of the present disclosure, the display substrate further includes: a spacer located at a side of the first electrode layer away from the base substrate. An orthographic projection of the spacer on the base substrate overlaps orthographic projections of the first protruding structure and the gate electrode electrically connected to the first protruding structure on the base substrate, and sizes of the spacer are larger than those of the second protruding structure in both the first direction and the second direction.

For example, according to an embodiment of the present disclosure, the first electrodes and the second electrodes of the plurality of transistors are arranged on the same layer as the plurality of gate lines.

For example, according to an embodiment of the present disclosure, the display substrate further includes: a second electrode layer, on the same layer as the plurality of first connecting portions, the plurality of sub-pixels sharing the second electrode layer, and the second electrode layer including a plurality of strip electrodes overlapping the first electrode layer in a direction perpendicular to the base substrate. The first electrode layer is located between a film layer where the plurality of gate lines are located and the film layer where the plurality of data lines are located, and in the direction perpendicular to the base substrate, the plurality of data lines overlap the second electrode layer.

For example, according to an embodiment of the present disclosure, the display substrate further includes: a plurality of second connecting portions, on the same layer as the plurality of first connecting portions, and configured to connect the first electrodes of the plurality of transistors to corresponding data lines.

For example, according to an embodiment of the present disclosure, the display substrate further includes: an insulating layer, located between the plurality of second connecting portions and the base substrate. The insulating layer includes a plurality of first via holes, and the first electrode of the transistor and a data line electrically connected with the first electrode of the transistor are connected to a same second connecting portion through a same first via hole.

For example, according to an embodiment of the present disclosure, the display substrate further includes: an insulating layer, located between the plurality of first connecting portions and the base substrate. The insulating layer includes a second via hole and a third via hole, the first connecting portion is connected to the gate electrode of the transistor through the second via hole, and the first connecting portion is connected to the protruding structure through the third via hole.

An embodiment of the present disclosure provides a display apparatus, which includes the display substrate in any of the above examples.

For example, according to an embodiment of the present disclosure, the display apparatus has a resolution of 8 k.

### BRIEF DESCRIPTION OF DRAWINGS

In order to clearly illustrate the technical solution of the embodiments of the present disclosure, the drawings of the embodiments will be briefly described in the following; it is obvious that the described drawings are only related to some embodiments of the present disclosure and thus are not limitative of the present disclosure.

FIG. 1 is a schematic diagram of a partial plane structure of a display substrate.

FIG. 2 is a schematic diagram of a partial cross-sectional structure of a display device including the display substrate shown in FIG. 1, taken along a line AA′ shown in FIG. 1.

FIG. 3 is a schematic diagram of a partial plane structure of a display substrate provided according to an embodiment of the present disclosure.

FIG. 4 is a schematic diagram of a partial cross-sectional structure taken along a line BB′ shown in FIG. 3.

FIGS. 5 to 11 are schematic diagrams of different film layers in a display substrate.

FIG. 12 is a partial enlarged view of the display substrate shown in FIG. 3.

FIG. 13 is a partial enlarged view of the film layer shown in FIG. 8.

FIG. 14A is a partial enlarged view of the display substrate shown in FIG. 12.

FIG. 14B is a sectional view taken along the line DD′ shown in FIG. 14A.

FIG. 15 is a schematic block diagram of a display device provided according to an embodiment of the present disclosure.

### DETAILED DESCRIPTION

In order to make objects, technical details and advantages of the embodiments of the present disclosure apparent, the technical solutions of the embodiment will be described in a clearly and fully understandable way in connection with the drawings related to the embodiments of the present disclosure. It is obvious that the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the present application for disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects. The features “parallel”, “perpendicular” and “same” used in the embodiments of the present disclosure all include features such as “parallel”, “perpendicular” and “same” in the strict sense, and the cases having certain errors, such as “approximately parallel”, “approximately perpendicular”, “approximately the same” or the like, taking into account measurements and errors associated with the measurement of a particular quantity (e.g., limitations of the measurement system), and indicate being within an acceptable range of deviation for a particular value as determined by one of ordinary skill in the art. For example, “approximately” may indicate being within one or more standard deviations, or within 10% or 5% of the stated value. In the case that the quantity of a component is not specifically indicated below in the embodiments of the present disclosure, it means that the component may be one or more, or may be understood as at least one. “At least one” means one or more, and “plurality” means at least two. The “same layer” in the present disclosure refers to the structure formed by two (or more) structures formed by the same deposition process and patterned by the same patterning process, and their materials may be the same or different.

A power consumption of a television (TV) product mainly comes from a backlight structure, a system-on-chip (SOC) board, and a display panel, where the power consumption of the backlight structure accounts for 70% to 80%, the power consumption of the SOC system board accounts for 10% to 20%, and the power consumption of the display panel accounts for 10% to 20%. Therefore, the power consumption of the whole device may be effectively reduced by reducing the power consumption of the backlight structure. For example, the power consumption of the backlight structure may be reduced by reducing the brightness of the backlight structure. When the backlight brightness decreases, the brightness of the product may be kept at an almost same level by increasing the transmittance of the display panel. For example, the transmittance of the display panel needs to be increased by 40%, and by using the dual brightness enhancement film (DBEF), the power consumption of the display apparatus may be reduced by 70%˜80%.

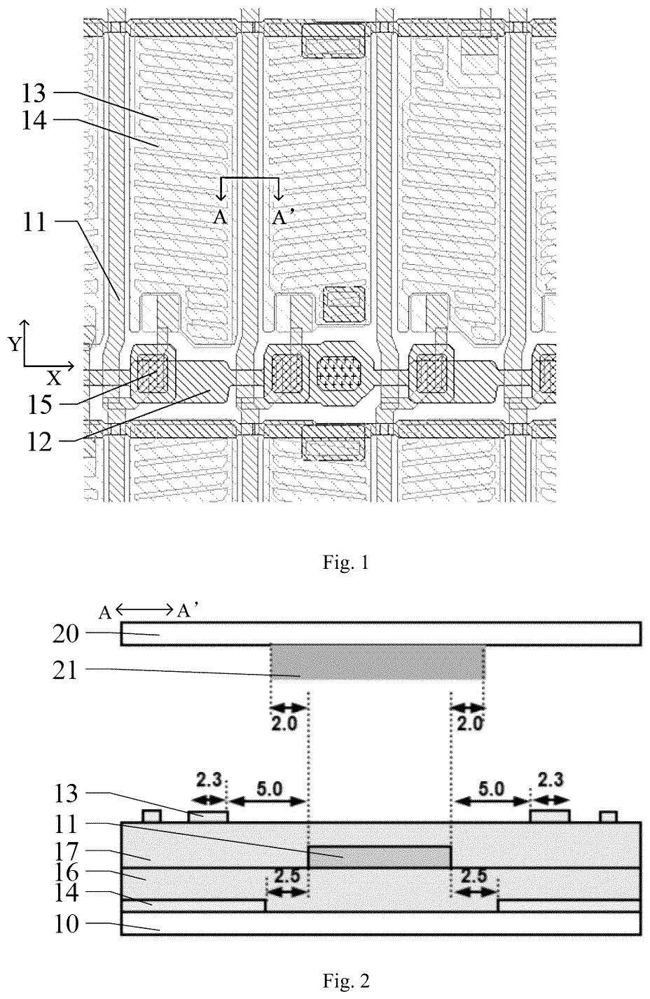

FIG. 1 is a schematic diagram of a partial plane structure of a display substrate, and FIG. 2 is a schematic diagram of a partial cross-sectional structure of a display device including the display substrate shown in FIG. 1, taken along a line AA′ shown in FIG. 1. As shown in FIG. 1 and FIG. 2, the display substrate includes a plurality of data lines 11 arranged in a X direction and a plurality of gate lines 12 arranged in a Y direction, where the plurality of data lines 11 and the plurality of gate lines 12 are insulated and intersected to limit a plurality of sub-pixels. Each sub-pixel includes a first electrode 13, a second electrode 14, and a transistor 15, where the first electrode 13 and the second electrode 14 are stacked, the gate line 12 is electrically connected with the gate electrode of the transistor 15 to control the transistor 15 to be turned on or off, the first electrode 13 is electrically connected to one of the source electrode and the drain electrode of the transistor 15, and the data line 11 is electrically connected to the other of the source electrode and the drain electrode of the transistor 15, and the data line 11 inputs a voltage signal required for a display screen through the transistor 15 to the first electrode 13 to realize the display of the display apparatus including the display substrate. The display substrate uses the advanced super dimension switching (ADS) display mode. The first electrode 13 may be a pixel electrode, and the second electrode 14 may be a common electrode.

As shown in FIG. 2, the data line 11 is located between a film layer where the first electrode 13 is located and a film layer where the second electrode 14 is located, and the first electrode 13 is located on a side of the second electrode 14 away from the first base substrate 10. An insulating layer 16 is provided between a film layer where the second electrode 14 is located and a film layer where the data line 11 is located, such as an inorganic insulating layer. An insulating layer 17 is provided between the film layer where the first electrode 13 is located and the film layer where the data line 11 is located, such as an inorganic insulating layer. The first electrode 13 includes a plurality of strip electrodes, and the second electrode 14 may be a block electrode that does not overlap the data line 11 in a direction perpendicular to the first base substrate 10.

As shown in FIG. 2, the display apparatus further includes a second base substrate 20 opposite to the first base substrate 10, and a black matrix 21 is provided on a side of the second base substrate 20 facing the first base substrate 10 to shield the data line 11. FIG. 2 only schematically shows the black matrix on the second base substrate. For example, a side of the second base substrate facing the first base substrate may also be provided with a color film layer. For example, a liquid crystal layer is provided between the first base substrate and the second base substrate.

As shown in FIG. 1 and FIG. 2, considering the driving capacity and process capacity of the data line 11, a line width of the data line 11 may be 4 microns to 10 microns. The line width of data line 11 lower than 3 microns may result in the risk of etching and fracture, and the line width of data line 11 greater than 10 microns may result in an impact on the transmittance of display apparatus. For example, the line width of the data line 11 may be 5 microns to 8 microns, such that the transmittance may be within a demand range while satisfying the driving requirements, and the display apparatus may be a display apparatus with a resolution of 8K as shown in FIG. 2. For example, the screen of the display apparatus may be 65 inches, and the line width of the data line 11 may be 7 microns.

As shown in FIG. 1 and FIG. 2, in the X direction, a distance between the second electrode 14 and the data line 11 is 2 microns to 6 microns, such as 2.5 microns. When the distance between the second electrode 14 and the data line 11 in the X direction is lower than 2 microns, considering the process fluctuations, the second electrode 14 may overlap the data line 11, resulting in a large capacitance of the data line 11. When the distance between the second electrode 14 and the data line 11 in the X direction is greater than 6 microns, the display apparatus may have a high transmittance loss. In addition, when designing the distance between the second electrode and the data line in the X direction, it is also necessary to consider a parasitic capacitance generated between the second electrode and the data line. The larger the capacitance, the more electric field the second electrode absorbs from the data line, the smaller the coupling of the data line to the first electrode, and the lower the risk of line Mura.

As shown in FIG. 1 and FIG. 2, the distance between the first electrode 13 and the data line 11 in the X direction is 2 microns to 7 microns, such as 5 microns, such as 6.5 microns. When the distance between the first electrode and the data line in the X direction is low, the first electrode may overlap the data line. When the distance between the first electrode and the data line in the X direction is high, the display apparatus has a high transmittance loss.

As shown in FIG. 1 and FIG. 2, in the X direction, a distance of a single side of the black matrix 21 beyond an edge of the data line 11 may be 2 microns to 8 microns, such as 2 microns. Because there is a slope on a width of the data line 11, and liquid crystal molecules at the slope have an inclination angle, the size above takes into account that the black matrix 21 needs to cover the slope of the data line 11 to prevent light leakage. For example, when a liquid crystal molecule is a negative liquid crystal, because the short axis direction of power supply is consistent with the direction of electric field, there is almost no light leakage problem, the black matrix exceeds the edge of data line by 2 microns in the width direction of data line, which can prevent light leakage.

In the study, an inventor of the present application found that the ADS display mode adopted by the display apparatus shown in FIG. 1 and FIG. 2 is limited by the pixel structure, and the width of a dark-field region at a place where the data line is located is about 12 microns, which affects the transmittance of the display apparatus. In order to reduce the width of a dark-field region, the display apparatus may apply an HADS display mode, in which the width of the dark-field region is lower than 12 microns, and when the process limits of the black matrix are taken into account, the width of the dark-field region may be reduced to 8 microns.

The embodiments of the present disclosure provide a display substrate and a display apparatus. The display substrate includes a base substrate and a plurality of data lines, a plurality of gate lines, a first electrode layer, and a plurality of transistors located on the base substrate. The plurality of data lines are arranged in a first direction, the plurality of gate lines are arranged in a second direction, and the second direction intersects the first direction. The first electrode layer is located on a side of a film layer where the plurality of data lines are located away from the base substrate. Each transistor includes a gate electrode, a first electrode and a second electrode. Gate electrodes of the plurality of transistors are electrically connected to the plurality of gate lines, first electrodes of the plurality of transistors are electrically connected to the plurality of data lines, and second electrodes of the plurality of transistors are electrically connected to the first electrode layer. The plurality of gate lines are located on a side of the plurality of data lines away from the base substrate, the gate electrodes of the plurality of transistors are arranged on the same layer as the plurality of data lines, and an orthographic projection of the gate electrode of at least one transistor on the base substrate is spaced apart from an orthographic projection of the gate line electrically connected to the gate electrode of the at least one transistor on the base substrate.

In the display substrate provided in the present disclosure, the data line is located between the gate line and the base substrate, and the orthographic projection of the gate electrode of the at least one transistor is spaced apart from the orthographic projection of the gate line, so that the flatness of the film layer in the display substrate can be improved to improve the uniformity of the film layer used for alignment and the film layer with spacers, and the transmittance of the display substrate can be improved while the complexity of the preparation process remains unchanged.

The display substrate and display apparatus provided in the embodiments of the present disclosure are described below with reference to the accompanying drawings.

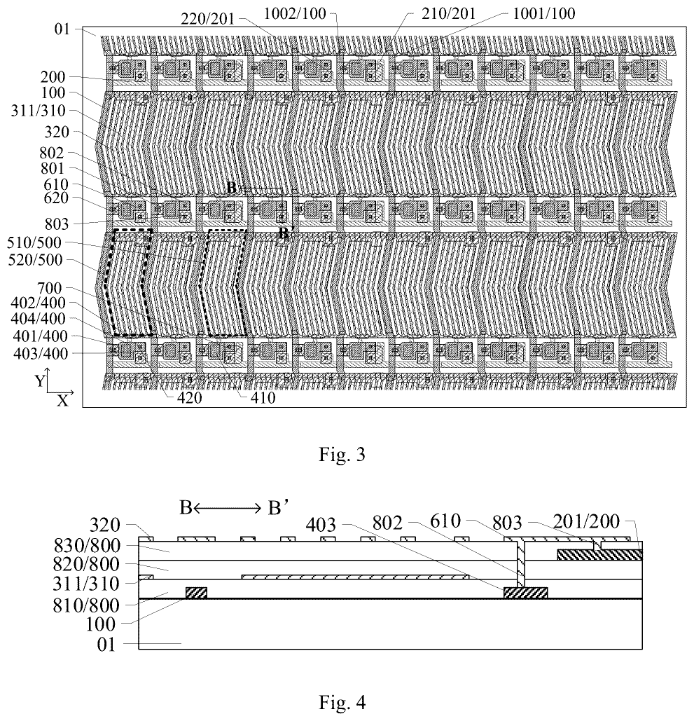

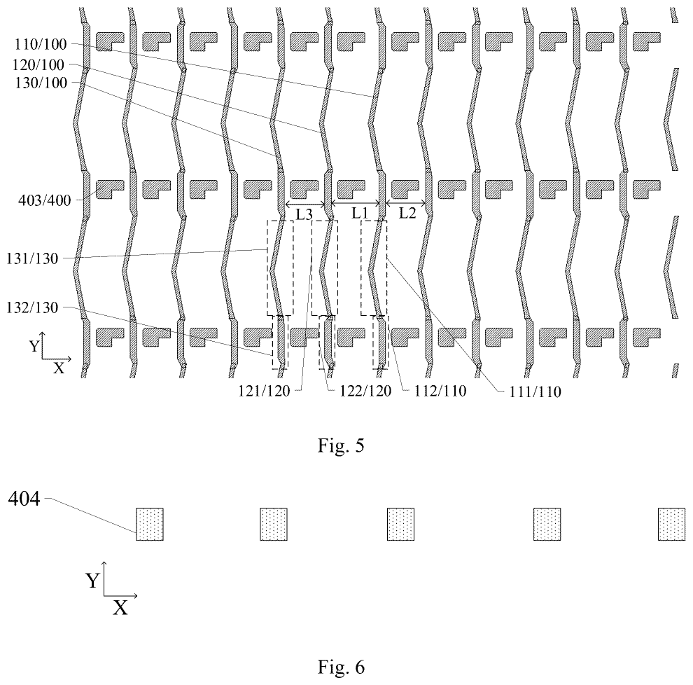

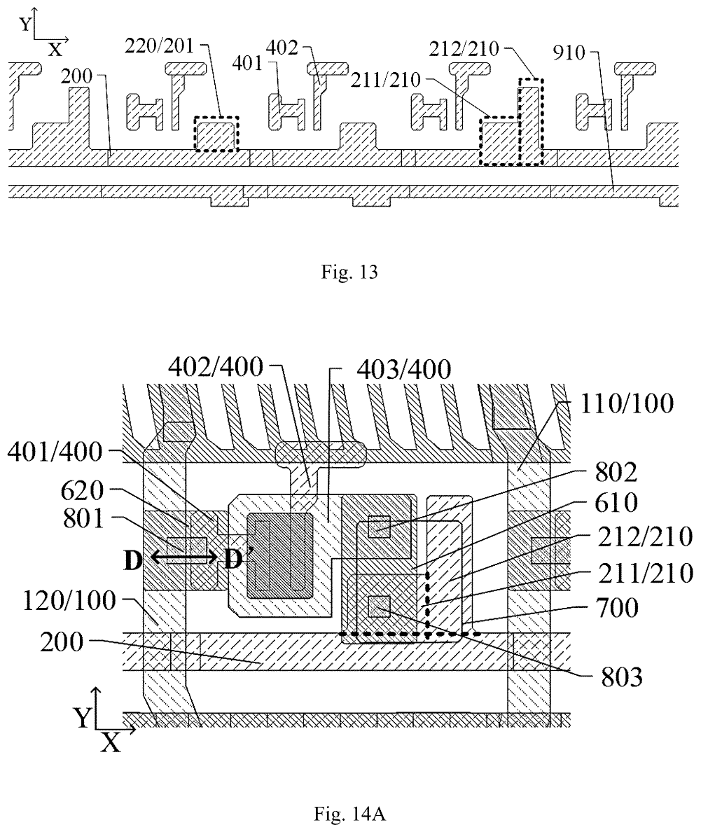

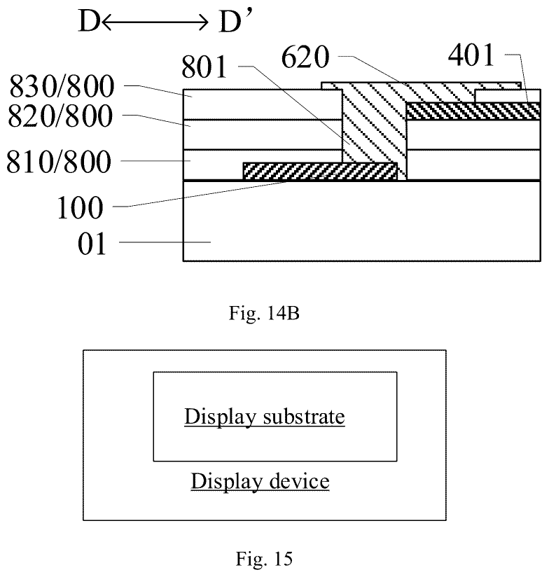

FIG. 3 is a schematic diagram of a partial plane structure of a display substrate provided according to an embodiment of the present disclosure. FIG. 4 is a schematic diagram of a partial cross-sectional structure taken along a line BB′ shown in FIG. 3. FIGS. 5 to 11 are schematic diagrams of different film layers in a display substrate. FIG. 12 is a partial enlarged view of the display substrate shown in FIG. 3. FIG. 13 is a partial enlarged view of the film layer shown in FIG. 8. FIG. 14A is a partial enlarged view of the display substrate shown in FIG. 12.

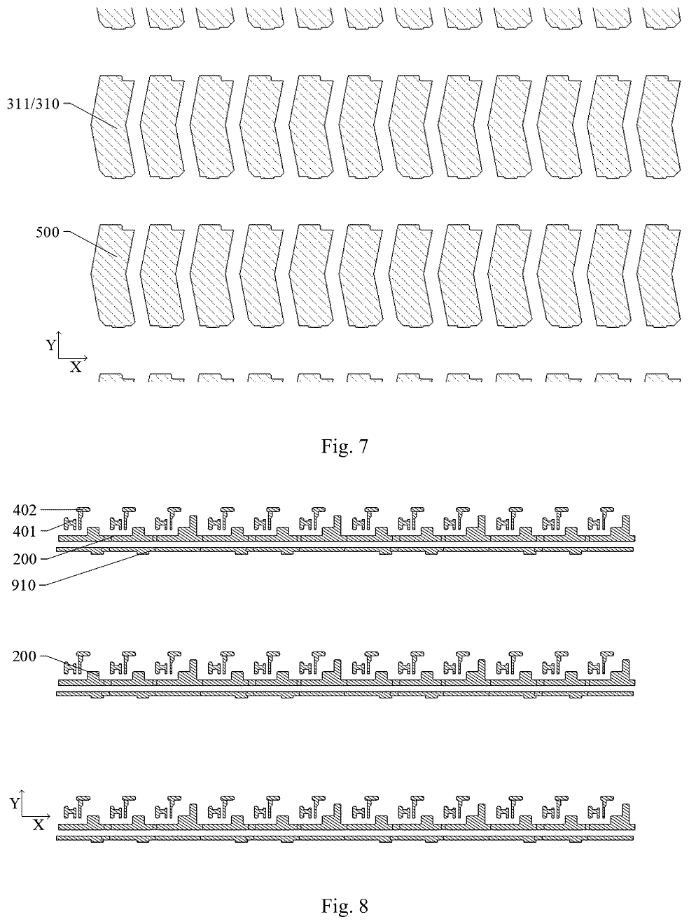

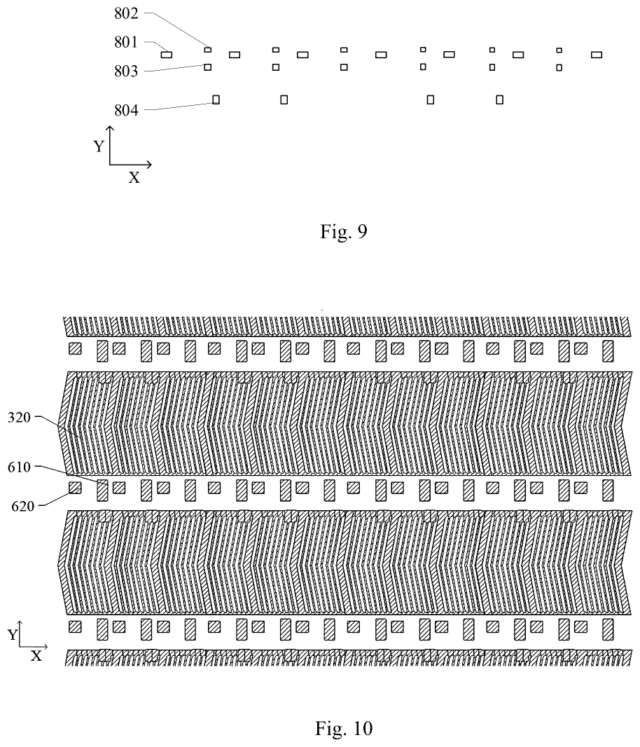

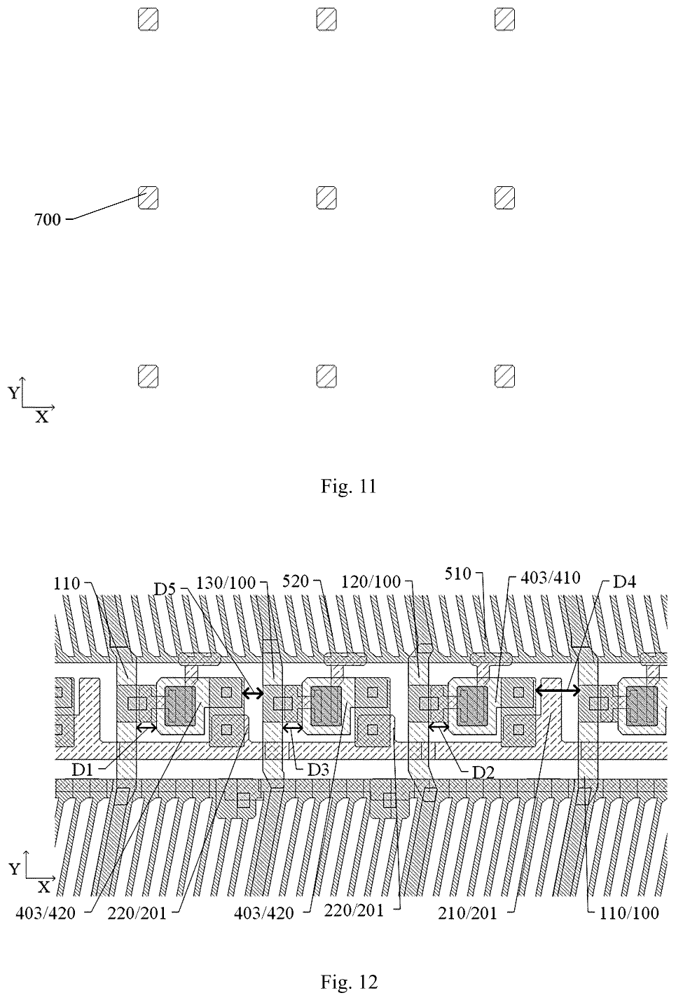

FIG. 5 is a film layer where the data line is located, FIG. 6 is a partial schematic diagram of a film layer where an active layer is located, FIG. 7 is a film where the first electrode layer is located, FIG. 8 is a film where the gate line is located, FIG. 9 is a partial schematic diagram of via holes, FIG. 10 is a film layer where the second electrode layer is located, and FIG. 11 is a film layer where the spacer is located.

As shown in FIG. 3 and FIG. 4, the display substrate includes a base substrate 01 and a plurality of data lines 100, a plurality of gate lines 200, a first electrode layer 310, and a plurality of transistors 400 located on the base substrate 01. The plurality of data lines 100 are arranged in a first direction, such as a X direction, and the plurality of gate lines 200 are arranged in a second direction, such as a Y direction, where the first direction intersects with the second direction. For example, the first direction is interchangeable with the second direction. For example, the first direction is perpendicular to the second direction. For example, an angle between the first direction and the second direction may be 80 degrees to 100 degrees.

In some examples, as shown in FIG. 3, the plurality of data lines 100 and the plurality of gate lines 200 are intersected to define a plurality of pixel areas, each of which is provided with one sub-pixel 500. For example, the display substrate includes a plurality of sub-pixels 500. For example, the plurality of sub-pixels 500 are arranged in an array in the first direction and second direction.

As shown in FIG. 3 and FIG. 4, the first electrode layer 310 is located on a side of a film layer where the plurality of data lines 100 are located away from the base substrate 01. For example, the first electrode layer 310 may be made of a material, including a transparent conductive material such as indium tin oxide (ITO).

In some examples, as shown in FIG. 2 and FIG. 7, the first electrode layer 310 includes a plurality of first electrodes 311 spaced apart from each other, and each of the sub-pixels 500 includes one of the first electrodes 311. For example, each first electrode 311 may be a block electrode. For example, each sub-pixel 500 may include two domains. For example, the first electrode 311 may be a pixel electrode. For example, in the X direction, a distance between the first electrode 311 and the data line 100 is greater than 3 microns to prevent them from overlapping each other.

As shown in FIG. 3, FIG. 5, FIG. 8, and FIG. 12 to FIG. 14A, each transistor 400 includes a gate electrode 403, a first electrode 401 and a second electrode 402, where gate electrodes 403 of the plurality of transistors 400 are electrically connected to the plurality of gate lines 200, first electrodes 401 of the plurality of transistors 400 are electrically connected to the plurality of data lines 100, and second electrodes 402 of the plurality of transistors 400 are electrically connected to the first electrode layer 310. For example, the gate line 200 controls the turn-on or turn-off of the transistor 400, and the data line 100 inputs a voltage signal required for a display screen through the first electrode 311 of the transistor 400 of the sub-pixels 500 to realize the display of the display apparatus including the display substrate.

For example, one of the first electrode 401 and the second electrode 402 is a source electrode and the other one thereof is a drain electrode. For example, the transistor 400 may be a thin-film transistor or a field-effect transistor or other switching device with the same characteristics. The source electrode and the drain electrode of the transistor herein may be structurally symmetrical, such that the source electrode and the drain electrode may be structurally similar. In an embodiment of the present disclosure, in order to distinguish two electrodes of the transistors other than the gate electrode, one electrode thereof is directly described as the first electrode and the other electrode thereof is the second electrode. Therefore, the first electrode and the second electrode of all or part of the transistors in the embodiments of the present disclosure are interchangeable as needed. For example, the first electrode of the transistor described in the embodiments of the present disclosure may be the source electrode and the second electrode thereof may be the drain electrode. Alternatively, the first electrode of the transistor is the drain electrode and the second electrode is the source electrode. In addition, the transistors may be categorized into N-type transistors and P-type transistors according to their characteristics. The transistors provided in the embodiments of the present disclosure may be N-type transistors or P-type transistors as needed.

For example, as shown in FIG. 3 and FIG. 6, the transistor 400 further includes an active layer 404, which overlaps the gate electrode 403, the first electrode 401, and the second electrode 402 of the transistor 400. In the display substrate provided in the present disclosure, the gate electrode of the transistor is provided on the same layer as the data line, and the data line and the gate line are film layers which are interchanged, whereby the transistor is a bottom gate structure.

In some examples, as shown in FIG. 3 and FIG. 8, the first electrode 401 and the second electrode 402 of the transistor 400 are both provided on the same layer as the plurality of gate lines 200.

As shown in FIG. 3 and FIG. 4, the plurality of gate lines 200 are located on a side of the plurality of data lines 100 away from the base substrate 01, the gate electrodes 403 of the plurality of transistors 400 are arranged on the same layer as the plurality of data lines 100, and an orthographic projection of the gate electrode 403 of the at least one transistor 400 on the base substrate 01 is spaced apart from an orthographic projection of the gate line 200 electrically connected to the gate electrode 403 of the at least one transistor 400 on the base substrate. For example, in a direction perpendicular to the base substrate 01, the gate electrode 403 of the at least one transistor 400 does not overlap the plurality of gate lines 200. For example, the gate electrode 403 of at least one transistor 400 in other transistors 400 except the above-mentioned at least one transistor 400 overlaps parts of the plurality of gate lines 200. For example, an orthographic projection on the substrate of the gate electrode of at least one of the other transistors 400, except for the at least one transistor 400 mentioned above, overlaps the orthographic projection on the substrate of the gate line.

In the display substrate provided in the present disclosure, the data line is disposed between the gate line and the base substrate, and the gate electrode of the at least one transistor is set as not overlapping an orthographic projection of the gate line, thereby improving the flatness of the film layer in the display substrate without increasing the complexity of the preparation process, which in turn increases uniformity of a film layer used for alignment and uniformity of a film layer provided with a spacer, and improves transmittance of the display substrate.

For a display substrate that typically applies the HADS display mode, an organic insulating layer is located between the data line and the electrode (ITO) on a side of the data line away from the base substrate to increase the distance between the data line and the electrode. However, compared with the display substrate that applies the ADS display mode, the display substrate that applies the HADS display mode increases the process of preparing the organic insulating layer, thereby increasing the process complexity.

Compared with the display apparatus that typically applies the ADS display mode, in the display substrate provided in the present disclosure, interchanging the film layer of the data line and the film layer of the gate line not only provides a large distance between the data line and the electrode, such as the second electrode layer (described below) to reduce a coupling capacitance therebetween and reduces the load of the data line, but also may maintain the same preparation process as the display substrate that applies the ADS display mode to achieve the same process complexity, and improve the transmittance of the display substrate.

For example, the display substrate provided in the present disclosure may be applied to a display apparatus with a resolution of 8K. For example, a screen size of the display apparatus of 65 inches may increase the transmittance by 24% compared with the display apparatus that applies the ADS display mode. A screen size of 75 inches of the display apparatus may increase the transmittance by 28% compared with the display apparatus that applies the ADS display mode.

In some examples, as shown in FIG. 3, FIG. 4, FIG. 10, FIG. 12, and FIG. 14A, the display substrate further includes a plurality of first connecting portions 610 located on a side of the plurality of gate lines 200 away from the base substrate 01, and the first connecting portions 610 are configured to connect the gate electrodes 403 of the plurality of transistors 400 to the plurality of gate lines 200. At least one of the gate lines 200 includes a plurality of protruding structures 201. For example, each gate line 200 includes plurality of protruding structures 201. For example, the plurality of protruding structures 201 in each gate line 200 are provided in a one-to-one correspondence to one row of sub-pixels 500 corresponding to the gate line 200.

For example, as shown in FIG. 13, the protruding structure 201 in the gate line 200 is a part of the gate line 200, the gate line 200 includes a linear structure extending in the X direction and protruding structures 201 connected with the linear structure, and the protruding structure 201 is a part protruding to the second electrode 402 of the transistor with respect to the linear structure. For example, in the at least one gate line 200, the plurality of protruding structures 201 are located in the same side of the linear structure.

In some examples, as shown in FIG. 3, FIG. 4, FIG. 10, FIG. 12, and FIG. 14A, each protruding structure 201 is configured to be electrically connected to the gate electrode 403 of the corresponding transistor 400 through at least one of the first connecting portions 610. The embodiments of the present disclosure schematically show that one protruding structure is electrically connected to the gate electrode of the transistor through one of the first connecting portions, but is not limited thereto, and one protruding structure may also be electrically connected to the gate electrode of a transistor through two or more of the first connecting portions.

For example, as shown in FIG. 8, a straight line extending in the X direction passes through the protruding structure 201 and the first electrode 401 and the second electrode 402 of the transistor to provide a compact structure. For example, the first electrode 401 and the second electrode 402 of the same transistor are located between two adjacent protruding structures 201.

For example, as shown in FIG. 13 and FIG. 14A, the first electrode 401 of the transistor is shaped as an H-like shape. For example, the first electrode 401 of the transistor includes a first portion and a second portion that extending in the Y direction and a third portion connecting the first portion and the second portion, where at least a part of the first portion overlaps the second connecting portion 620 (as described below), and at least a part of the second portion overlaps the active layer 404, and a size of the first portion in the Y direction is greater than a size of the second portion in the Y direction, and a size of the first portion in the X direction is greater than a size of the second portion in the X direction. For example, the size of the first portion in the X direction may be more than ten microns, and the size of the first portion in the Y direction is greater than the size thereof in the X direction. Configuring a small size for the second portion and a large size for the first portion may facilitate reducing the parasitic capacitance, while improving the conduction effect between the first portion and a via hole.

For example, as shown in FIG. 14A, the second electrode 402 of the transistor includes a fourth portion extending in the X direction and a fifth portion extending in the Y direction to form a T-like shape.

For example, as shown in FIG. 3 and FIG. 12, the gate electrode 403 does not overlap the protruding structure 201 in the direction perpendicular to the base substrate 01 to improve the flatness of the display substrate and prevent the uneven alignment of the film layer located on a side of the protruding structure and the gate electrode away from the base substrate from affecting the liquid crystal deflection during the alignment process. For example, in response to that the at least one gate electrode does not overlap the protruding structure, at least one gate electrode may be configured as overlapping the protruding structure by a larger size to provide flatness at different positions of the gate electrode to match the position of the spacer.

In some examples, as shown in FIG. 3 and FIG. 12, the plurality of protruding structures 201 include at least a first protruding structure 210 and a second protruding structure 220, the plurality of sub-pixels 500 include at least a first sub-pixel 510 and a second sub-pixel 520, the transistor 400 electrically connected to the first electrode 311 of the first sub-pixel 510 is a first transistor 410, and the transistor 400 electrically connected to the first electrode 311 of the second sub-pixel 520 is a second transistor 420. The gate electrode 403 of the first transistor 410 is electrically connected to the first protruding structure 210, the gate electrode 403 of the second transistor 420 is electrically connected to the second protruding structure 220, and the shape of the first protruding structure 210 is different from that of the second protruding structure 220.

The display substrate provided in the present disclosure is configured to be different in the shape of the first protruding structure and the second protruding structure to match the shape of the spacer.

In some examples, as shown in FIG. 3, and FIG. 11 to FIG. 13, the first protruding structure 210 has an area larger than that of the second protruding structure 220.

In some examples, as shown in FIG. 3 and FIG. 12, the display substrate further includes a spacer (PS) 700 located on a side of the first electrode layer 310 away from the base substrate 01, an orthographic projection of the spacer 700 on the base substrate 01 overlaps an orthographic projection of the first protruding structure 210 and an orthographic projection of the gate electrode 403 electrically connected to the first protruding structure 210 on the base substrate 01, and sizes of the spacer 700 are larger than those of the second protruding structure 220 in both the first and second directions.

For example, as shown in FIG. 3 and FIG. 12, more than 50 percent of the area of the orthographic projection of the spacer 700 on the base substrate 01 falls into the orthographic projection of the first protruding structure 210 and the gate electrode 403 on the base substrate 01. For example, more than 80 percent of the orthographic projection of the spacer 700 on the base substrate 01 falls within the orthographic projection of the first protruding structure 210 and the gate electrode 403 on the base substrate 01. For example, more than 90 percent of the orthographic projection of the spacer 700 on the base substrate 01 falls within the orthographic projection of the first protruding structure 210 and the gate electrode 403 on the base substrate 01. For example, less than 50 percent of the orthographic projection of the spacer 700 on the base substrate 01 falls within the orthographic projection of the gate electrode 403 on the base substrate 01. For example, less than 40 percent of the orthographic projection of the spacer 700 on the base substrate 01 falls within the orthographic projection of the gate electrode 403 on the base substrate 01. For example, the orthographic projection of the spacer 700 on the base substrate 01 does not overlap the orthographic projection of the second protruding structure 220 on the base substrate 01.

Because of the large size of the spacer, by setting the first protruding structure to have a larger area than that of the second protruding structure, a large part of the spacer may be overlapped with the first protruding structure, and a small part of the spacer may be overlapped with the gate electrode, thereby improving the flatness of the film layer between the spacer and the base substrate without affecting the transistor performance and color display.

For example, as shown in FIG. 3, the plurality of sub-pixels 500 include a red sub-pixel, a green sub-pixel, and a blue sub-pixel, where the first sub-pixel 510 may be a red sub-pixel, and the second sub-pixel 520 may be a green sub-pixel or a blue sub-pixel to comprehensively consider the opening ratio and color temperature of the display substrate. For example, gate electrodes of transistors of sub-pixels with the same color do not overlap the gate line. For example, gate electrodes of transistors of red sub-pixels do not overlap the gate line. For example, the gate electrodes of the transistors of respective sub-pixels do not overlap the gate lines.

For example, as shown in FIG. 11, there may be a plurality of spacers 700, and each red sub-pixel is provided with a spacer, and the plurality of spacer 700 are uniformly spaced apart. For example, the plurality of spacer 700 may be of the same shape, but they are not limited thereto, and the plurality of spacers may also include spacers of different shapes, such as including primary spacers and auxiliary spacers, where the primary spacer has a volume greater than that of the auxiliary spacer, and the number of the primary spacers is lower than the number of auxiliary spacers.

In some examples, as shown in FIG. 13 and FIG. 14A, the first protruding structure 210 includes a first sub-protruding structure 211 and a second sub-protruding structure 212, and the first sub-protruding structure 211 and the second protruding structure 220 are of substantially the same shape and are substantially equal in size. For example, the first sub-protruding structure 211 and the second sub-protruding structure 212 are integrated structures. For example, the first sub-protruding structure 211 and the second protruding structure 220 have a polygonal shape. For example, both the first sub-protruding structure 211 and the second protruding structure 220 have a rectangular shape, such as a standard rectangle, or a rounded rectangle, or a chamfered rectangle, or the like.

For example, as shown in FIG. 14A, the first connecting portion 610 does not overlap the second sub-protruding structure 212 in the direction perpendicular to the base substrate 01 to improve the flatness of the film layer between the spacer and the base substrate.

For example, the second sub-protruding structure 212 has a shape different from the first sub-protruding structure 211. For example, the second sub-protruding structure 212 have a polygonal shape. For example, the second sub-protruding structure 212 has a rectangular shape, such as a standard rectangle, or a rounded rectangle, or a chamfered rectangle, or the like.

In some examples, as shown in FIG. 14A, the second sub-protruding structure 212 is located on a side of the first sub-protruding structure 211 away from the gate electrode 403 electrically connected to the first sub-protruding structure 211. For example, the second sub-protruding structure 212 is located between the first sub-protruding structure 211 and the data line 100 closest to the first sub-protruding structure 211.

In some examples, as shown in FIG. 14A, in the second direction, the size of the second sub-protruding structure 212 is larger than that of the first sub-protruding structure 211.

For example, as shown in FIG. 14A, a straight line extending in the X direction passes through the gate electrode 403 and the second sub-protruding structure 212. For example, the size of the first protruding structure 210 in the X direction is greater than the size of the spacer 700 in the X direction, and the dimension of the second sub-protruding structure 212 in the Y direction is greater than the size of the spacer 700 in the Y direction.

In the display substrate provided in the present disclosure, the setting of the size relationship and position relationship of the first protruding structure and the spacer facilitates the improving of the flatness of the film layer between the spacer and the base substrate without affecting the transistor performance and the display color.

For example, as shown in FIG. 3 and FIG. 12, a distance D4 between the gate electrode 403 of the first transistor 410 and the data line 100 located on the right side thereof is greater than a distance D5 between the gate electrode 403 of the second transistor 420 and the data line 100 on the right side thereof, such that the second sub-protruding structure 212 is disposed between the gate electrode 403 of the first transistor 410 and the data line 100, and a spacer is arranged on the first protruding structure. The arrow in the X direction points to the right, and the arrow in the Y direction points upward.

In some examples, as shown in FIG. 3 and FIG. 12, in the first direction, a ratio of a distance between the first protruding structure 210 and the closest data line 100 thereof to a distance between the second protruding structure 220 and the closest data line 100 thereof is in a range from 0.8 to 1.2. For example, in the first direction, the ratio of the distance between the first protruding structure 210 and the closest data line 100 thereof to the distance between the second protruding structure 220 and the closest data line 100 thereof is in a range from 0.9 to 1.1. In the first direction, the distance between the first protruding structure 210 and the closest data line 100 thereof equals to the distance between the second protruding structure 220 and the closest data line 100 thereof. For example, the data line 100 closest to the first protruding structure 210 may be the data line 100 on a side of the first protruding structure away from the corresponding gate electrode 403, and the data line 100 closest to the second protruding structure 220 may be the data line 100 on a side of the second protruding structure away from the corresponding gate electrode 403.

In the display substrate provided in the present disclosure, while the first protruding structure and the second protruding structure are different in size in the first direction, the distance between the first protruding structure and the data line is configured as approximately equal to the distance between the second protruding structure and the data line, which facilitates minimizing the influence of the difference in the protruding structure on the sub-pixels of different colors.

In some examples, as shown in FIG. 3, the data line 100 closest to the first protruding structure 220 is shaped differently from the data line 100 closest to the second protruding structure 220. For example, the data line 100 closest to the first protruding structure 210 is a first sub data line 1001, and the data line 100 closest to the second protruding structure 220 is a second sub data line 1002. The sub-pixels 500 provided in the X direction are one row of sub-pixels, the shape of a portion between two adjacent sub-pixels 500 in the same row of the first sub data line 1001 is approximately the same as the shape of a portion between two adjacent sub-pixels 500 in the same row of the second sub data line 1002, and the shape of a portion between sub-pixels 500 in adjacent rows of the first sub data line 1001 is different from the shape of a portion between sub-pixels 500 in adjacent rows of the second sub data line 1002 to match the shape of the data line to the shapes of the first protruding structure and the second protruding structure without affecting the opening ratio.

In some examples, as shown in FIG. 5 and FIG. 12, two data lines 100 located on both sides of the first protruding structure 210 include a first data line 110 and a second data line 120, two data lines 100 located on both sides of the second protruding structure 220 include the second data line 120 and a third data line 130 or the first data line 110 and a third data line 130, and the first data line 110 or the second data line 120 is located between the first protruding structure 210 and the second protruding structure 220, and the first data line 110, the second data line 120, and the third data line 130 have different shapes.

For example, as shown in FIG. 3 and FIG. 5, the shape of a portion 111, between two adjacent sub-pixels 500 in the same row, of the first data line 110, the shape of a portion 121, between two adjacent sub-pixels 500 in the same row, of the second data line 120, and the shape of a portion 131, between two adjacent sub-pixels 500 in the same row, of the third data line 130 are all approximately the same, and the shape of a portion 112, between sub-pixels 500 in adjacent rows, of the first data line 110, the shape of a portion 122, between sub-pixels 500 in adjacent rows, of the second data line 120, and the shape of a portion 132, between sub-pixels 500 in adjacent rows, of the third data line 130 are all different, such that the shape of the data line matches with the shapes of the first protruding structure and the second protruding structure without affecting the opening ratio.

In some examples, as shown in FIG. 5 and FIG. 12, the first data line 110 and the second data line 120 bent to two sides away from the first protruding structure 210 at positions corresponding to the first protruding structure 210. For example, the portion of the first data line 110 and the portion of the second data line 120 between sub-pixels 500 in adjacent rows are bent on both sides away from the first protruding structure 210, respectively. For example, the data line 100 located on the right side of the first protruding structure 210 is bent to the right, and the data line 100 located on the left side of the first protruding structure 210 is bent to the left. Bending the portions of the first data line and the second data line between the adjacent row sub-pixels on both sides away from the first protruding structure may avoid the first protruding structure and the spacer.

In some examples, as shown in FIG. 12, a distance between the first data line 110 and the gate electrode 403 closest to the first data line 110 is a first distance D1, a distance between the second data line 120 and the gate electrode 403 closest to the second data line 120 is a second distance D2, a distance between the third data line 130 and the gate electrode 403 closest to the third data line 130 is a third distance D3, and a ratio of the first distance D1, the second distance D2 and the third distance D3 is (0.8-1.2):(0.8-1.2):(0.8-1.2). For example, the ratio of the first distance D1, the second distance D2 and the third distance D3 is (0.9-1.1):(0.9-1.1):(0.9-1.1). For example, the first distance D1, the second distance D2, and the third distance D3 are substantially equal to each other.

In the display substrate provided in the present disclosure, while the first data line, the second data line, and the third data line are different in shape, configuring the first distance, the second distance, and the third distance as substantially equal to each other may facilitate minimizing the influence of the difference in the protruding structure on the sub-pixels of different colors.

In some examples, as shown in FIG. 3, FIG. 5, FIG. 8, and FIG. 12, the shape of the gate electrode 403 of the first transistor 410 is approximately the same as that of the gate electrode 403 of the second transistor 420, the shape of the first electrode 401 of the first transistor 410 is approximately the same as that of the first electrode 401 of the second transistor 420, and the shape of the second electrode 402 of the first transistor 410 is approximately the same as that of the second electrode 402 of the second transistor 420. Configuring shapes of respective electrodes of the first transistor and the second transistor as approximately the same does not increase the process complexity.

In some examples, as shown in FIG. 12, a ratio of a distance between the gate electrode 403 of the first transistor 410 and the data line 100 electrically connected to the first transistor 410 to a distance between the gate electrode 403 of the second transistor 420 and the data line 100 electrically connected to the second transistor 420 is in a range from 0.8 to 1.2. For example, a ratio of the second distance D2 to the first distance D1 is in a range from 0.8 to 1.2, or a ratio of the second distance D2 to the third distance D3 is in a range from 0.8 to 1.2. For example, the ratio of the distance between the gate electrode 403 of the first transistor 410 and the data line 100 electrically connected to the first transistor 410 to the distance between the gate electrode 403 of the second transistor 420 and the data line 100 electrically connected with the second transistor 420 is in a range from 0.9 to 1.1. The distance between the gate electrode 403 of the first transistor 410 and the data line 100 electrically connected to the first transistor 410 is approximately equal to the distance between the gate electrode 403 of the second transistor 420 and the data line 100 electrically connected to the second transistor 420.

In the display substrate provided in the present disclosure, while setting the shape of respective electrodes of the first transistor and the second transistor as approximately the same, and the shape of the data line electrically connected to the first transistor as different from the shape of the data line electrically connected to the second transistor, setting the distance between the gate electrode of the first transistor and the data line as approximately equal to the distance between the gate electrode of the second transistor and the data line may facilitate minimizing the influence of the difference in the protruding structure on the sub-pixels of different colors.

For example, as shown in FIG. 5 and FIG. 12, the first data line 110, the second data line 120, and the third data line 130 are provided in a cyclic manner in the X direction. For example, a distance L1 of two portions, of the first data line 110 and the second data line 120, between sub-pixels 500 in adjacent rows is greater than a distance L2 of two portions, of the first data line 110 and the third data line 130, between sub-pixels 500 in adjacent rows and a distance L3 of two portions, of the second data line 120 and the third data line 130, between sub-pixels 500 in adjacent rows. For example, the L2 and the L3 are substantially equal to each other. A ratio of the L1 to the L2 should not be too large to prevent at least one of the first data line and second data line from having too much resistance. For example, the ratio of the L1 to the L2 is not greater than 1.5, for example, not greater than 1.4, for example, not greater than 1.3, and for example, not greater than 1.2. The distances L1, L2, and L3 are the distances between edges of two data lines that are close to each other.

For example, as shown in FIG. 5, a plurality of gate electrodes 403 of the plurality of transistors are arranged non-uniformly to match the positions of the gate electrode, the protruding structure, and the data line.

In some examples, as shown in FIG. 3, FIG. 4 and FIG. 10, the display substrate further includes a second electrode layer 320, where the second electrode layer 320 is provided on the same layer as the plurality of first connecting portions 610. For example, the second electrode layer 320 may be made of a transparent conductive material such as indium tin oxide (ITO). For example, the second electrode layer 320 includes a second electrode located in each sub-pixel and a connecting portion connected to adjacent second electrodes, where the second electrode is located in an emitting region of the sub-pixel and the connecting portion is located in a non-emitting region.

In some examples, as shown in FIG. 3, FIG. 4 and FIG. 10, the plurality of sub-pixels 500 share the second electrode layer 320, and the second electrode layer 320 may be a common electrode.

In some examples, as shown in FIG. 3, FIG. 4, and FIG. 10, the second electrode layer 320 includes a plurality of strip electrodes that overlap the first electrode layer 310 in the direction perpendicular to the base substrate 01. For example, the second electrode layer 320 is stacked with the first electrode layer 310 to form a capacitance. The first electrode layer 310 is located between the film layer where the plurality of gate lines 200 are located and the film layer where the plurality of data lines 100 are located, and the data line 100 overlaps the second electrode layer 320 in the direction perpendicular to the base substrate 01.

For example, as shown in FIG. 3, FIG. 4, and FIG. 10, the second electrode layer 320 includes a strip electrode with a line width of 2.2 microns and adjacent strip electrodes may be spaced apart by a distance of 5.4 microns. For example, a size of the second electrode layer 320 beyond an edge of the data line 100 may be greater than 1.5 microns to ensure that the second electrode layer 320 may still cover the data line 100 under a condition of process fluctuation. For example, a shortest distance between an edge of a portion where the second electrode layer 320 covers the data line 100 and an edge of the data line 100 is similar to a line width of the strip electrode. For example, a ratio therebetween may be 0.9 to 1.1. For example, the shortest distance may be 2.1 microns, which may not only provide the best light effect design, but also avoid the problem of color crossover at an oblique angle under the minimum size of the black matrix. For example, a width of a shading portion between adjacent openings in the black matrix may be 8 microns.

Setting the data line between the gate line and the base substrate facilitates reducing parasitic capacitance between the data line and the second electrode layer.

For example, as shown in FIG. 3, FIG. 8, and FIG. 9, the display substrate further includes a common electrode line 910, where the common electrode line 910 is electrically connected to the second electrode layer 320 through a via hole 804. For example, the common electrode line 910 is on the same layer as the gate line 200. For example, the common electrode lines 910 and the gate lines 200 are alternatively provided in the Y direction.

In some examples, as shown in FIG. 3, FIG. 10, and FIG. 14A, the display substrate further includes a plurality of second connecting portions 620, where the plurality of second connecting portions 620 are disposed on the same layer as the plurality of first connecting portions 610, and configured to connect the first electrodes 401 of the plurality of transistors 400 to the corresponding data lines 100. For example, the second connecting portion 620 does not overlap the gate electrode 403 of the transistor in the direction perpendicular to the base substrate 01 to improve the flatness of the base substrate. For example, the size of the first connecting portion 610 in the Y direction is greater than the size of the second connecting portion 620 in the Y direction.

In some examples, as shown in FIG. 3, FIG. 4, FIG. 9, and FIG. 14A, the display substrate further includes an insulating layer 800, the insulating layer 800 is located between the plurality of second connecting portions 620 and the base substrate 01, for example, between the second electrode layer 320 and the base substrate 01. The insulating layer 800 includes a plurality of first via holes 801, and the first electrode 401 of the transistor 400 and the data line 100 electrically connected therewith are connected to the same second connecting portion 620 through the same first via hole 801.

FIG. 14B is a sectional view taken along the line DD′ shown in FIG. 14A. For example, as shown in FIG. 14B, the first electrode 401 of the transistor 400 does not overlap the data line 100 in the direction perpendicular to the base substrate 01, to prevent climbing of the second connecting portion 620 in the first via hole 801, which may affect the electrical conductivity. Of course, the embodiments of the present disclosure are not limited thereto, and the first electrode of the transistor and the data line may be electrically connected through two different via holes. Alternatively, in the direction perpendicular to the base substrate, the first electrode of the transistor overlaps the data line, and they are electrically connected through a via hole penetrating the insulating layer therebetween.

For example, as shown in FIG. 14A, considering the overlapping resistance of the first via 801, a size of an overlapping portion of the first via 801 and the data line 100 is greater than 3 microns, such as greater than 4 microns. For example, the size of the first via 801 may be 8 microns. When the first via hole 801 is a round hole, the diameter of the circular hole is 8 microns, and when the first via hole is a strip hole, the length of the strip hole is 8 microns. For example, a size of the second connecting portion 620 beyond an edge of the first via hole 801 may be 3 microns, such as 4 microns, and the like.

For example, as shown in FIG. 14A, the first connecting portion 610 includes two edges extending in the second direction, the first connecting portion 610 covers an edge of the gate line 403 extending in the second direction, one of the two edges of the first connecting portion 610 is protruding with respect to the edge of the gate electrode 403, the first connecting portion 610 covers an edge of the first sub-protruding structure 211 extending in the second direction, and the other edge of the two edges of the first connecting portion 610 is protruding relative to the edge of the first sub-protruding structure 211. For example, an edge extending in the Y direction on the right side of the first connecting portion 610 is farther away from the geometric center of the gate electrode 403 than an edge extending in the Y direction on the rightmost side of the gate electrode 403, and an edge extending in the Y direction on the left side of the first connecting portion 610 is farther away from the geometric center of the first sub-protruding structure 211 than an edge extending in the Y direction on the left side of the first sub-protruding structure 211, so as to ensure the electrical connection effect of a second via hole and a third via hole.

In some examples, as shown in FIG. 3, FIG. 4, FIG. 9, and FIG. 14A, the display substrate further includes an insulating layer 800, where the insulating layer 800 is located between the plurality of first connecting portions 610 and the base substrate 01, for example, between the second electrode layer 320 and the base substrate 01. The insulating layer 800 includes a second via hole 802 and a third via hole 803, the first connecting portion 610 is connected to the gate electrode 403 of the transistor 400 through the second via hole 802, and the first connecting portion 610 is connected to the protruding structure 201 through the third via hole 803.

For example, as shown in FIG. 4, the insulating layer 800 includes a first insulating layer 810 located between the first electrode layer 310 and the data line 100, a second insulating layer 820 located between the gate line 200 and the first electrode layer 310, and a third insulating layer 830 located between the second electrode layer 320 and the gate line 200. The first connecting portion 610 is electrically connected to the gate electrode 403 of the transistor through the second via hole 802 penetrating the first insulating layer 810, the second insulating layer 820, and the third insulating layer 830, and the first connecting portion 610 is electrically connected to the gate line 200 through the third via hole 803 penetrating the third insulating layer 830. For example, a portion of the second connecting portion 620 is electrically connected to the data line 100 through a part of the first via hole 801 penetrating the first insulating layer 810, the second insulating layer 820, and the third insulating layer 830, and another part of the second connecting portion 620 is electrically connected to the first electrode 401 of the transistor through another part of the first via hole 801 penetrating the third insulating layer 830. The sizes of the second hole and the third via hole may be designed with reference to the size design of the first via hole.

FIG. 15 is a schematic block diagram of a display device provided according to an embodiment of the present disclosure.

As shown in FIG. 15, a display apparatus provided in another embodiment of the present disclosure includes the display substrate provided in any one of the examples above.

In some examples, the display apparatus has a resolution of 8 k. But it is not limited thereto, and the display apparatus may also be a display apparatus with other resolutions, such as a resolution of 16K, or the like.

For example, the display apparatus may be a liquid crystal display apparatus. For example, the display substrate described above may be an array substrate, and the display apparatus may further include an opposing substrate provided opposite to the display substrate. For example, the opposing substrate may include a black matrix as well as a color film layer. For example, the display apparatus may also include a liquid crystal layer that is located between the array base substrate and the opposing substrate.

The following statements should be noted:
(1) The accompanying drawings involve only the structure(s) in connection with the embodiment(s) of the present disclosure, and other structure(s) can be referred to common design(s).
(2) In case of no conflict, features in one embodiment or in different embodiments can be combined.

What have been described above are only specific implementations of the present disclosure, the protection scope of the present disclosure is not limited thereto. The protection scope of the present disclosure should be based on the protection scope of the claims.

1. A display substrate, comprising:
a base substrate;
a plurality of data lines, located on the base substrate, the plurality of data lines being arranged in a first direction;
a plurality of gate lines, located on the base substrate, the plurality of gate lines being arranged in a second direction, and the second direction intersecting with the first direction;
a first electrode layer, located on a side of a film layer where the plurality of data lines are located away from the base substrate;
a plurality of transistors, located on the base substrate, each of the plurality of transistors comprising a gate electrode, a first electrode and a second electrode, gate electrodes of the plurality of transistors being electrically connected to the plurality of gate lines, first electrodes of the plurality of transistors being electrically connected to the plurality of data lines, and second electrodes of the plurality of transistors being electrically connected to the first electrode layer;
wherein the plurality of gate lines are located on a side of the plurality of data lines away from the base substrate, the gate electrodes of the plurality of transistors are arranged on the same layer as the plurality of data lines, and an orthographic projection of the gate electrode of at least one transistor on the base substrate is spaced apart from an orthographic projection of a gate line electrically connected to the gate electrode of the at least one transistor on the base substrate.

2. The display substrate according to claim 1, further comprising:
a plurality of sub-pixels, the first electrode layer comprising a plurality of first electrodes arranged at intervals, and each sub-pixel comprising one of the plurality of first electrodes;
a plurality of first connecting portions, located on a side of the plurality of gate lines away from the base substrate, and configured to connect the gate electrodes of the plurality of transistors to the plurality of gate lines;
wherein at least one gate line comprises a plurality of protruding structures, each protruding structure is configured to be electrically connected to the gate electrode of a corresponding transistor through at least one of the plurality of first connecting portions, and the plurality of protruding structures comprise at least a first protruding structure and a second protruding structure;
the plurality of sub-pixels comprise at least a first sub-pixel and a second sub-pixel, a transistor electrically connected to the first electrode of the first sub-pixel is a first transistor, a transistor electrically connected to the first electrode of the second sub-pixel is a second transistor, the gate electrode of the first transistor is electrically connected to the first protruding structure, the gate electrode of the second transistor is electrically connected to the second protruding structure, and a shape of the first protruding structure is different from that of the second protruding structure.

3. The display substrate according to claim 2, wherein an area of the first protruding structure is larger than that of the second protruding structure.

4. The display substrate according to claim 2, wherein the first protruding structure comprises a first sub-protruding structure and a second sub-protruding structure, and the first sub-protruding structure and the second protruding structure are of substantially a same shape and are substantially equal in size.

5. The display substrate according to claim 4, wherein the second sub-protruding structure is located on a side of the first sub-protruding structure away from the gate electrode electrically connected to the first sub-protruding structure.

6. The display substrate according to claim 5, wherein, in the second direction, a size of the second sub-protruding structure is larger than a size of the first sub-protruding structure.

7. The display substrate according to claim 2, wherein, in the first direction, a ratio of a distance between the first protruding structure and a data line closest to the first protruding structure to a distance between the second protruding structure and a data line closest to the second protruding structure is in a range from 0.8 to 1.2.

8. The display substrate according to claim 2, wherein the data line closest to the first protruding structure has a different shape from the data line closest to the second protruding structure.

9. The display substrate according to claim 8, wherein two data lines located on both sides of the first protruding structure comprise a first data line and a second data line, two data lines located on both sides of the second protruding structure comprise the second data line and a third data line or the first data line and a third data line, and the second data line or the first data line is located between the first protruding structure and the second protruding structure, and the first data line, the second data line, and the third data line have different shapes.

10. The display substrate according to claim 9, wherein the first data line and the second data line, at positions corresponding to the first protruding structure, bent to two sides away from the first protruding structure.

11. The display substrate according to claim 9, wherein a distance between the first data line and a gate electrode closest to the first data line is a first distance, a distance between the second data line and a gate electrode closest to the second data line is a second distance, a distance between the third data line and a gate electrode closest to the third data line is a third distance, and a ratio of the first distance, the second distance, and the third distance is (0.8˜1.2):(0.8˜1.2):(0.8˜1.2).

12. The display substrate according to claim 2, wherein a shape of the gate electrode of the first transistor is approximately the same as that of the gate electrode of the second transistor, a shape of the first electrode of the first transistor is approximately the same as that of the first electrode of the second transistor, and a shape of the second electrode of the first transistor is approximately the same as that of the second electrode of the second transistor; and
a ratio of a distance between the gate electrode of the first transistor and a data line electrically connected to the first transistor to a distance between the gate electrode of the second transistor and a data line electrically connected to the second transistor is in a range from 0.8 to 1.2.

13. The display substrate according to claim 2, further comprising:
a spacer located at a side of the first electrode layer away from the base substrate,
wherein an orthographic projection of the spacer on the base substrate overlaps orthographic projections of the first protruding structure and the gate electrode electrically connected to the first protruding structure on the base substrate, and sizes of the spacer are larger than those of the second protruding structure in both the first direction and the second direction.

14. The display substrate according to claim 1, wherein the first electrodes and the second electrodes of the plurality of transistors are arranged on the same layer as the plurality of gate lines.

15. The display substrate according to claim 2, further comprising:
a second electrode layer, on the same layer as the plurality of first connecting portions, the plurality of sub-pixels sharing the second electrode layer, and the second electrode layer comprising a plurality of strip electrodes overlapping the first electrode layer in a direction perpendicular to the base substrate,
wherein the first electrode layer is located between a film layer where the plurality of gate lines are located and the film layer where the plurality of data lines are located, and in the direction perpendicular to the base substrate, the plurality of data lines overlap the second electrode layer.

16. The display substrate according to claim 2, further comprising:
a plurality of second connecting portions, on the same layer as the plurality of first connecting portions, and configured to connect the first electrodes of the plurality of transistors to corresponding data lines.

17. The display substrate according to claim 16, further comprising:
an insulating layer, located between the plurality of second connecting portions and the base substrate,
wherein the insulating layer comprises a plurality of first via holes, and the first electrode of the transistor and a data line electrically connected with the first electrode of the transistor are connected to a same second connecting portion through a same first via hole.

18. The display substrate according to claim 2, further comprising:
an insulating layer, located between the plurality of first connecting portions and the base substrate,
wherein the insulating layer comprises a second via hole and a third via hole, the first connecting portion is connected to the gate electrode of the transistor through the second via hole, and the first connecting portion is connected to the protruding structure through the third via hole.

19. A display apparatus, comprising the display substrate according to claim 1.

20. The display apparatus according to claim 19, wherein the display apparatus has a resolution of 8 k.
